(19) United States
(12) Patent Application Publication
(10) Pub. No.: US 2014/0175055 A1
(43) Pub. Date: Jun. 26, 2014

(54) ADJUSTABLE COIL FOR INDUCTIVELY COUPLED PLASMA

(71) Applicant: QUALCOMM MEMS TECHNOLOGIES, INC., San Diego, CA (US)

(72) Inventor: Teruo Sasagawa, Los Gatos, CA (US)

(73) Assignee: QUALCOMM MEMS Technologies, Inc., San Diego, CA (US)

(21) Appl. No.: 13/725,251

(22) Filed: Dec. 21, 2012

(51) Int. Cl. C23C 16/505; B44C 1/22

(52) U.S. Cl. CPC C23C 16/505; B44C 1/227
USPC 216/68; 118/723 I; 156/345.48; 427/569

(57) ABSTRACT

Systems, methods and apparatus for fabricating devices use an inductively-coupled plasma. An inductively coupled plasma system includes a reaction chamber including a reaction space and a coil chamber. The system includes a workpiece support within the reaction space. The system includes a first inductive coil section and a second inductive coil section, the first and second inductive coil sections being independently movable. At least one power source is coupled to the first and second inductive coil sections. The first and second inductive coil sections and the at least one power source are configured to induce an inductively coupled plasma (ICP) in the reaction space. An adjustment mechanism is configured to move the first inductive coil section relative to the second inductive coil section.

### TECHNICAL FIELD

This disclosure relates to a plasma system, and more particularly, to an inductively-coupled plasma system.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

The aforementioned electromechanical systems devices can be fabricated using various processing tools and systems. Conventional semiconductor fabrication equipment, such as chemical vapor deposition (CVD), plasma-enhanced CVD, and etching tools, have been adapted for fabricating display panels. However, new challenges are being found in obtaining the desired uniformity for large rectangular substrates often used to form displays. Such substrates can be employed for MEMS displays, such as the IMOD display technology described above, as well as other display technologies, such as LCD, LED, OLED, etc.

### SUMMARY

The systems, methods and devices of this disclosure each have several innovative aspects, no single one of which is solely responsible for the desirable attributes disclosed herein.

One innovative aspect of the subject matter described in this disclosure can be implemented in an inductively coupled plasma system. The inductively coupled plasma system includes a reaction chamber. The reaction chamber includes a reaction space and, a coil chamber. The inductively coupled plasma system further includes a workpiece support within the reaction space. The inductively coupled plasma system further includes a first inductive coil section and a second inductive coil section within the coil chamber. The first and second inductive coil sections are independently movable. The inductively coupled plasma system further includes at least one power source coupled to the first and second inductive coil sections. The first and second inductive coil sections and the at least one power source are configured to induce an inductively coupled plasma in the reaction space. The inductively coupled plasma system further includes an adjustment mechanism configured to move the first inductive coil section relative to the second inductive coil section.

In some implementations, the at least one power source can be a single power source communicating with both the first and second inductive sections. In some implementations, the adjustment mechanism can include one or more stepper motors. In some implementations, the one or more stepper motors can include a stepper motor for each of the first and second inductive coil sections. In some implementations, the adjustment mechanism can be configured to be moved automatically. In some implementations, the inductively coupled plasma system can include an isolating partition between the coil chamber and the reaction space, and the adjustment mechanism can be configured to move the first inductive coil section relative to the isolating partition. In some implementations, the inductively coupled plasma system can further include additional inductive coil sections within the coil chamber, and the system can further include separate adjustment mechanisms for each of the first, second and additional inductive coil sections. In some implementations, the inductively coupled plasma system can further include a flexible connector configured to electrically couple the first and second inductive coil sections. In some implementations, the first and second inductive coil sections can form at least part of a pattern of inductive coil sections within the coil chamber collectively having an approximately rectangular shape.

Another innovative aspect of the subject matter described in this disclosure can be implemented in a method of plasma-processing a workpiece. The method includes providing a reaction chamber that includes a first inductive coil section and a second inductive coil section, and at least one power source coupled to the first and second inductive coil sections. The first and second inductive coil sections and the at least one power source are configured to induce an inductively coupled plasma in the reaction chamber. The first inductive coil section is moved relative to the second inductive coil section with an adjustment mechanism.

In some implementations, the first inductive coil section can be automatically moved. In some implementations, the first inductive coil section can be moved relative to the second inductive coil section with a stepper motor. In some implementations, the first inductive coil section can be moved relative to an isolating partition positioned between a coil chamber within which the first and second inductive coil sections are located and a reaction space of the reaction chamber. In some implementations, additional inductive coil sections can be provided within the coil chamber, and the first, second, and additional inductive coil sections can be moved with separate adjustment mechanisms. In some implementations, a processing gas can be injected into a reaction space of the reaction chamber, and an inductively coupled plasma can be induced in the reaction space from the processing gas. In some implementations, a workpiece positioned on a workpiece support within the reaction space can be etched with the inductively coupled plasma. In some implementations, a film can be deposited on a workpiece positioned on a workpiece support within the reaction space with the inductively coupled plasma.

Another innovative aspect of the subject matter described in this disclosure can be implemented in an inductively coupled plasma system. The inductively coupled plasma system includes a reaction space. The inductively coupled plasma system further includes a workpiece support within the reaction space. The inductively coupled plasma system further includes a means for inducing an inductively coupled plasma in the reaction space. The inductively coupled plasma system further includes adjustment means for moving a first section of the means for inducing relative to a second section of the means for inducing.

In some implementations, the adjustment means includes a stepper motor. In some implementations, the adjustment means includes a separate stepper motor for each of the first and second sections of the means for inducing. In some implementations, the means for inducing includes means for adjusting relative power distribution between the first and second sections.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Additionally, the concepts provided herein may apply to other types of devices, such as semiconductor and integrated circuits. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 is a flow diagram illustrating a manufacturing process for an IMOD display or display element.

FIGS. 2A-2E are cross-sectional illustrations of various stages in a process of making an IMOD display or display element.

FIG. 3 is an example of a cross-sectional side view of an inductively-coupled plasma system, in accordance with one implementation.

FIG. 4 is an example of a cross-sectional side view of an inductively-coupled plasma system, in accordance with another implementation.

FIG. 5A is an example of a top plan view of a plurality of inductive coil sections with a plurality of adjustment mechanisms, in accordance with an implementation.

FIG. 5B is an example of a top plan view of a plurality of inductive coil sections showing electrical connections among sections, in accordance with an implementation.

FIG. 6 is an example of a cross-sectional side view of an inductively-coupled plasma etch system, in accordance with an implementation.

FIG. 7 is an example of a top plan view of a plurality of inductive coil sections with a corresponding plurality of adjustment mechanisms, in accordance with an implementation.

FIG. 8 is an example of a top plan view of a plurality of inductive coil sections, in accordance with another implementation.

FIG. 9 is an example of a system block diagram illustrating an inductively-coupled plasma system including a plasma reactor and a control system, in accordance with an implementation.

FIG. 10 is example of a flow diagram illustrating a method of plasma-processing a substrate, in accordance with an implementation.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in apparatuses, systems, and processes to fabricate any device, apparatus, or system, such as those configured to display an image, whether in motion (such as video) or stationary (such as still images), and whether textual, graphical or pictorial. More particularly, it is contemplated that the described implementations may be associated with fabrication of a variety of electronic devices such as, but not limited toelectromechanical systems (EMS) applications including microelectromechanical systems (MEMS) applications, as well as non-EMS applications. The teachings herein also can be used in fabrication of non-display electronic devices. Thus, the teachings are not intended to be limited to the implementations depicted solely in the Figures, but instead have wide applicability as will be readily apparent to one having ordinary skill in the art.

An inductively-coupled plasma (ICP) system is disclosed that can be used to fabricate a device (e.g., a MEMS or integrated circuit device). The ICP system can include a reaction space and a workpiece support within a reaction chamber. The system can be configured to perform an ICP process within the reaction space on a workpiece supported by the workpiece support. The system can induce a plasma with a first inductive coil section, a second inductive coil section, and a power source. An adjustment mechanism, such as a stepper motor, can be configured to move the first inductive coil section relative to the second inductive coil section, and/or other components within the ICP system. Relative movement of different coil sections allows tuning the plasma process for greater uniformity of process effect across the workpiece. The system can be implemented to perform different IPC processes, such as plasma etch, plasma deposition (such as uniform high quality CVD deposition), and plasma annealing.

Particular implementations of the subject matter described in this disclosure can be implemented to realize one or more of the following potential advantages. A first and second inductive coil section that can be moved relative to each other can provide separate control of plasma zones during plasma formation within the reaction space, which in turn can provide control of processing zones across the workpiece. Inductive coil sections that are configured to move relative to each other can simplify and reduce system costs relative, for example, to zoning by altering power distribution among coil sections, while providing zoned control over the rate, uniformity, or other ICP process parameters. Alternatively, such mechanical zoning can be employed as a supplemental tuning mechanism in addition to altering power distribution.

Implementations can be applied, for example, to manufacturing display devices and/or EMS devices. An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

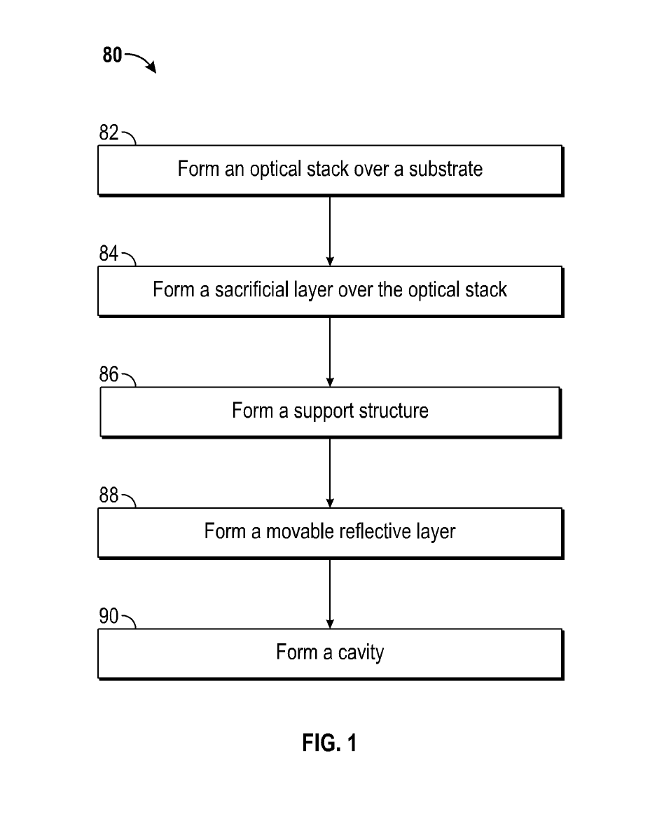

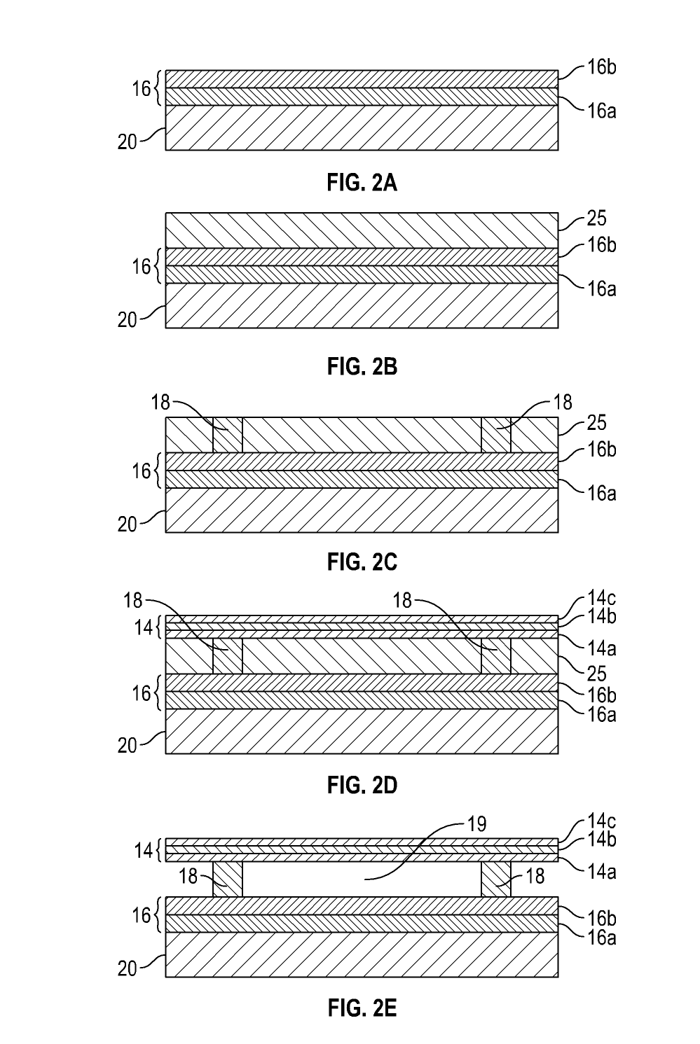

FIG. 1 is a flow diagram illustrating a manufacturing process 80 for an IMOD display or display element. FIGS. 2A-2E are cross-sectional illustrations of various stages in a manufacturing process 80 for making an IMOD display or display element. In some implementations, the manufacturing process 80 can be implemented to manufacture arrays of EMS devices, such as IMOD displays. The manufacture of such an EMS device also can include other blocks not shown in FIG. 1. The process 80 begins at block 82 with the formation of an optical stack 16 over a substrate 20. FIG. 2A illustrates such an optical stack 16 formed over the substrate 20. The substrate 20 may be a substrate such as a glass substrate (sometimes referred to as a workpiece, glass plate or panel). The glass substrate may be or include, for example, a borosilicate glass, a soda lime glass, quartz, Pyrex, or other suitable glass material. Example substrates include standard formats, including G1 (˜300 mm×350 mm); G2 (˜370 mm×470 mm); G3 (˜550 mm×650 mm); G4 (˜730 mm×920 mm); G5 (˜1100 mm×1250 mm); G6 (˜1500 mm×1850 mm); G7 (˜1950 mm×2200 mm); G8 (˜2200 mm×2400 mm); G10 (˜2880 mm×3130 mm); In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. In some implementations, the substrate may be or include silicon, or other materials used in IC manufacturing. The substrate 20 may be flexible or relatively stiff and unbending, and may have been subjected to prior preparation processes, such as cleaning, to facilitate efficient formation of the optical stack 16. The optical stack 16 can include an electrically conductive layer, and can be partially transparent, partially reflective and partially absorptive, and may be fabricated, for example, by depositing one or more layers having the desired properties onto the transparent substrate 20.

In FIG. 2A, the optical stack 16 includes a multilayer structure having sub-layers 16a and 16b, although more or fewer sub-layers may be included in some other implementations. In some implementations, one of the sub-layers 16a and 16b can be configured with both optically absorptive and electrically conductive properties, such as a combined conductor/absorber sub-layer 16a. In some implementations, one of the sub-layers 16a and 16b can include a semireflective thickness of a metallic material, such as molybdenum-chromium (molychrome or MoCr), or other materials with a suitable complex refractive index. Additionally, one or more of the sub-layers 16a and 16b can be patterned into parallel strips, and may form row electrodes in a display device. Such patterning can be performed by a masking and etching process or another suitable process known in the art. In some implementations, one of the sub-layers 16a and 16b can be an insulating or dielectric layer, such as an upper sub-layer 16b that is deposited over one or more underlying metal and/or oxide layers (such as one or more reflective and/or conductive layers). In addition, the optical stack 16 can be patterned into individual and parallel strips that form the rows of the display. In some implementations, at least one of the sub-layers of the optical stack, such as the optically absorptive layer, may be quite thin (for example, relative to other layers depicted in this disclosure), even though the sub-layers 16a and 16b are shown somewhat thick in FIGS. 2A-2E.

The process 80 continues at block 84 with the formation of a sacrificial layer 25 over the optical stack 16. Because the sacrificial layer 25 is later removed (see block 90) to form a cavity 19 (see FIG. 2E), the sacrificial layer 25 is not present in the resulting IMOD display elements. FIG. 2B illustrates a partially fabricated device including a sacrificial layer 25 formed over the optical stack 16. The formation of the sacrificial layer 25 over the optical stack 16 may include deposition of a fluorine-etchable material such as molybdenum (Mo) or amorphous silicon (Si), in a thickness selected to provide, after subsequent removal, a gap or cavity 19 (see FIG. 2E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as a support post 18. The formation of the support post 18 may include patterning the sacrificial layer 25 to form a support structure aperture, then depositing a material (such as a polymer or an inorganic material, like silicon oxide) into the aperture to form the support post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the support post 18 contacts the substrate 20. Alternatively, as depicted in FIG. 2C, the aperture formed in the sacrificial layer 25 can extend through the sacrificial layer 25, but not through the optical stack 16. For example, FIG. 2E illustrates the lower ends of the support posts 18 in contact with an upper surface of the optical stack 16. The support post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 2C, but also can extend at least partially over a portion of the sacrificial layer 25. Patterning can include photolithography to mask the post regions with mask features slightly wider than the apertures, and a selective etch process designed to stop on the sacrificial layer 25. As noted above, the patterning of the sacrificial layer 25 and/or the support posts 18 can be performed by a masking and etching process, but also may be performed by alternative patterning methods. Such patterning and its selective etching processes are examples of processes that may be performed with implementations of the plasma apparatus and methods described further herein.

The process 80 continues at block 88 with the formation of a movable reflective layer or membrane such as the movable reflective layer 14 illustrated in FIG. 2D. The movable reflective layer 14 may be formed by employing one or more deposition steps, including, for example, reflective layer (such as aluminum, aluminum alloy, or other reflective materials) deposition, along with one or more patterning, masking and/or etching steps. The movable reflective layer 14 can be patterned into individual and parallel strips that form, for example, the columns of the display. The movable reflective layer 14 can be electrically conductive, and referred to as an electrically conductive layer. In some implementations, the movable reflective layer 14 may include a plurality of sub-layers 14a, 14b and 14c as shown in FIG. 2D. In some implementations, one or more of the sub-layers, such as sub-layers 14a and 14c, may include highly reflective sub-layers selected for their optical properties, and another sub-layer 14b may include a mechanical sub-layer selected for its mechanical properties. In some implementations, the mechanical sub-layer may include a dielectric material. Since the sacrificial layer 25 is still present in the partially fabricated IMOD display element formed at block 88, the movable reflective layer 14 is typically not movable at this stage. A partially fabricated IMOD display element that contains a sacrificial layer 25 also may be referred to herein as an “unreleased” IMOD.

The process 80 continues at block 90 with the formation of a cavity 19. The cavity 19 (FIG. 2E) may be formed by exposing the sacrificial material 25 (deposited at block 84) to an etchant. For example, an etchable sacrificial material such as Mo or amorphous Si may be removed by dry chemical etching by exposing the sacrificial layer 25 to a gaseous or vaporous etchant, such as vapors derived from solid XeF₂ for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD display element may be referred to herein as a “released” IMOD.

In some implementations, the packaging of a display, such as the IMOD-based display described above, can include a backplate (alternatively referred to as a backplane, back glass or recessed glass) which can be configured to protect the EMS components from damage (such as from mechanical interference or potentially damaging substances). The backplate also can provide structural support for a wide range of components, including but not limited to driver circuitry, processors, memory, interconnect arrays, vapor barriers, product housing, and the like. In some implementations, the use of a backplate can facilitate integration of components and thereby reduce the volume, weight, and/or manufacturing costs of a portable electronic device.

In some implementations, the fabrication of electronic devices, such as integrated circuits and displays, including but not limited to IMOD displays, can employ a plasma process, such as an plasma etch, plasma deposition, or plasma annealing process for a substrate. For example, a plasma-etch process may be employed to clean residual oxide or other materials from conductive contact surfaces prior to deposition of overlying conductors and/or to roughen surfaces of these devices at various stages of device fabrication. Such etching can be employed to improve electrical contact and/or adhesion of subsequent layers of material. A plasma deposition process may be employed to deposit metal, oxide, or other materials to form overlying conductors or other structures. A plasma annealing process may be employed to cure, crystallize or harden particular materials. In one implementation, a selective etching process for patterning an oxide post material while stopping on sacrificial material (see FIG. 2C and attendant description) can be a plasma etching process. In some implementations, such a plasma process can be an inductively coupled plasma (“ICP”) process, to provide, for example, high density plasma for rapidly processing the substrate.

An ICP processing system typically includes a reaction chamber with a workpiece support on or over which a substrate is positioned. The system typically includes a power source coupled to an inductive coil. A process gas is introduced into the reaction chamber, generally while the chamber is held to a low pressure, typically in the milliTorr range. An electric field established by the power source and inductive coil induces plasma to form from the process gas within the reaction chamber. The plasma can then be used to perform a plasma process on the substrate, such as plasma etch, plasma deposition, plasma annealing, or other plasma processes, for various types of ICP systems.

A relevant process parameter within an ICP process is the distribution of the plasma, or plasma density, within the reaction chamber. Such plasma distribution can affect the uniformity of the surface of a workpiece or substrate on which an ICP process is performed. Such plasma distribution, and thus workpiece uniformity, can be affected by the size and shape of the system components (for example, the inductive coil), and/or the workpiece, and/or the composition, temperature, flow, and other characteristics of the processing gas within the reaction chamber. As an example, for a selective plasma etch of oxide posts across a relatively large workpiece, stopping on a sacrificial material such as molybedenum, any nonuniformity in the plasma effect will cause differential times to remove the oxide from over the molybdenum. This can cause differential exposure of the sacrificial material to the plasma etchants, and thus, due to imperfect selectivity, differential thickness of remaining sacrificial material across the substrate, which can critically affect interferometrically reflected color. Thus, there is a need to tune plasma effect across the substrate.

One method of tuning uniformity of plasma effect is to tune power distributed across the ICP coil(s). For example, in some ICP systems, the plasma distribution can be affected by providing different amounts of energy to distinct “plasma zones” as the plasma is being formed within a plasma reaction space. These plasma zones can be individually controlled to affect the surface uniformity or other characteristics of corresponding “substrate zones” on the substrate being processed. These plasma zones and corresponding substrate zones can be implemented by adjusting the power provided by additional, separate power sources to multiple inductive coils. Another way to tune power distribution across the ICP coil is to separate coil sections within a single inductive coil. Such zones can also be provided by adjusting the flow of energy between sections of an inductive coil, for example, by positioning capacitors between the coil sections or otherwise distributing the electrical load across different sections of the coil. However, such electrical zoning implementations may, for example, be limited to a given number of zones. Thus, these implementations may limit the available adjustment to the plasma distribution and workpiece uniformity.

The plasma effect (for example, distribution of plasma densities) can also be affected by the positioning or movement of the inductive coil relative to components of the reaction chamber and/or the workpiece positioned within the reaction chamber. For example, the closer the coil to an isolating partition positioned between the coil and the reaction space, the more intense a plasma can be formed, which changes the effects of the ICP process on the workpiece in the reaction chamber.

Implementations of an ICP system and processes can include one or more adjustment mechanisms, such as stepper motors, that are configured to move two or more inductive coil sections relative to each other, or relative to other components within the ICP system, such as the isolating partition. Allowing such movement can improve control over plasma intensity across various zones within an ICP system, and hence improve uniformity within corresponding zones on a workpiece.

In some implementations, the adjustment mechanism(s), or the adjustment mechanism(s) in combination with one or more other components of the ICP system, such as the inductive coil(s), can be configured to be retrofit and/or easily replaceable, so that they can be used in conjunction with existing plasma processing equipment, to allow for use in any of a variety of plasma processes.

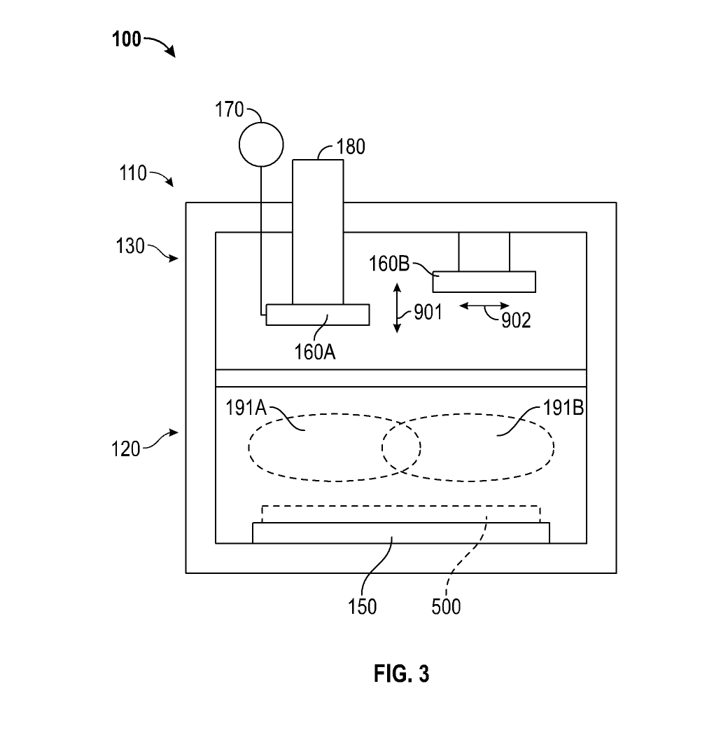

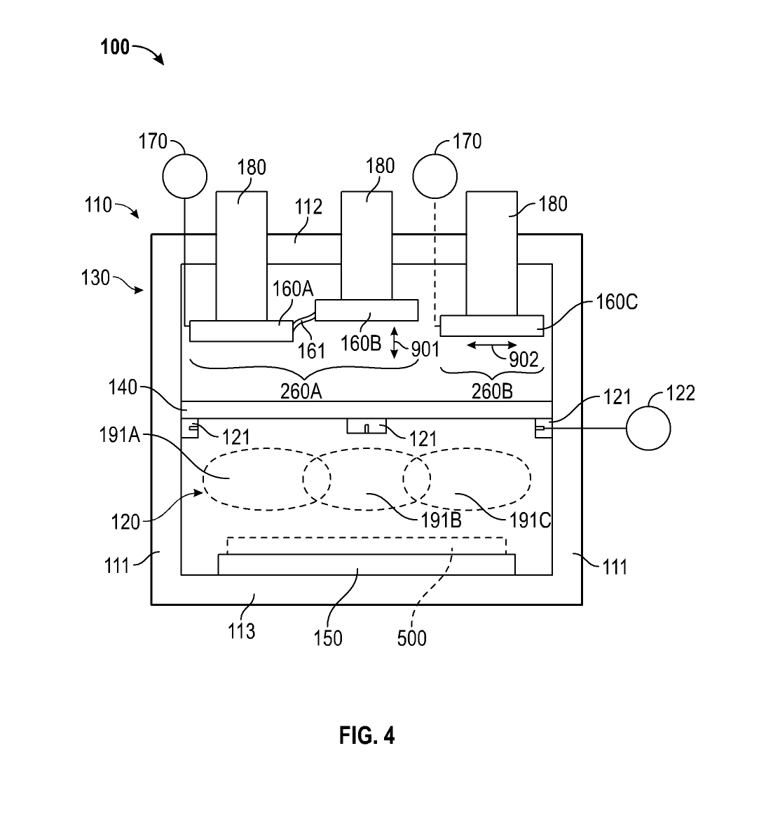

FIG. 3 is an example of a cross-sectional side view of an inductively-coupled plasma (ICP) system 100, in accordance with one implementation. FIG. 4 is an example of a cross-sectional side view of the inductively-coupled plasma system 100, in accordance with another implementation.

Referring to FIGS. 3 and 4, the ICP system 100 can include a reaction chamber 110 and a workpiece support 150 configured to support a substrate or workpiece 500 within a first (for example, lower) portion 120 of reaction chamber 110. Two or more inductive coil sections 160A and 160B can be positioned within a second (for example, upper) portion, or coil chamber 130 of the reaction chamber 110. One or more adjustment mechanisms 180 can be configured to move one or more of the coil sections relative to each other and/or other components of system 100. At least one power source 170 can be coupled to at least one of the first and second inductive coil sections 160A and 160B. FIG. 4 also shows a third coil section 160C. The first and second inductive coil sections 160A and 160B and the power source 170 can be configured to induce an inductively coupled plasma within a reaction space formed by an inner volume of the first portion 120 of the reaction chamber 110.

The reaction chamber 110 can be any shape suitable to support and conduct an ICP process on the workpiece 500 positioned and supported within an interior volume of the reaction chamber 110. The workpiece 500 can include any of a number of different workpieces used to form electromechanical system devices and/or integrated circuit devices, such as glass, silicon, and the like. In an implementation, the workpiece 500 can include a rectangular glass workpiece ranging from an industry-standard display panel size G1 (300×350 mm) to G10 (2880×3130 mm). The length of the workpiece 500 can range from about 350 mm to about 3130 mm, in one implementation; from about 470 mm to about 1850 mm, or from about 650 mm to about 1250 mm in another implementation. The width of the workpiece 500 can range from about 300 mm to about 2880 mm in one implementation; from about 370 mm to about 1500 mm in another implementation; or from about 550 mm to about 1100 mm in another implementation. In one example, the workpiece 500 can be a rectangular glass workpiece with a length×width of about 920 mm×730 mm.

The reaction chamber 110 can be any of a number of different shapes to form an interior volume within which a plasma can form in first portion 120 and perform a plasma process on a workpiece 500. For example, and referring to FIG. 4, chamber 110 can include sidewalls 111, a top 112 and a base 113. In one implementation, the interior volume of the first portion 120 of reaction chamber 110, within which the plasma can form can range from approximately 30 liters to 300 liters for G4.5 size glass. For G10 size, it can be 1500 liters or more. The chamber 110 can include any of many materials suitable for an ICP process, such as a metal and/or metal alloy (e.g., aluminum, stainless steel, etc.). Portions of the process chamber exposed to the plasma can be formed of a material resistant to the ICP processing gas and/or plasma, to reduce corrosion or erosion that may be caused by the ICP process. For example, the process chamber can include an aluminum alloy that has been anodized to provide chemical resistance from process gases within the process chamber. In some implementations, the chamber can include a ceramic coating, such as aluminum oxide (Al₂O₃), or yttrium oxide (Y₂O₃). In some implementations, a ceramic plate can be attached to the chamber to protect the portions of the chamber that may come in contact with the reactive plasma. The chamber 110 can be suitably configured to be sealed and held to a particular pressure (for example, a low pressure in the millitorr range) during at least portions of the ICP process.

Continuing to refer to FIG. 4, the reaction chamber 110 can include an isolating partition 140 configured to separate the first portion 120 from the second portion 130. Such separation can prevent contamination between the portions 120, 130. In some implementations, the partition 140 can be electrically insulating and can sealingly (in one implementation, hermetically) separate the first portion 120 from the second portion 130. For example, in some implementations, the first portion 120 can be controlled to a different pressure than the second portion 130. In some implementations, the first portion 120 can be evacuated to a low pressure (for example, in the milliTorr range). In some implementations, the second portion 130 can be controlled to an atmospheric pressure condition, or pressurized above atmosphere. The partition 140 can include any of a number of different materials with suitable rigidity and strength to provide the aforementioned separation between portions 120, 130, and compatible with an ICP process to be performed within chamber 110, such as a quartz or other ceramic material. In some implementations, the partition 140 can include a dielectric material. In some implementations, the second portion 130 can be filled (e.g., partially or substantially filled) with an insulating material to prevent electrical discharge and/or plasma formation within second portion 130. For example, second portion 130 can be filled with an insulating gas, such as sulfur hexafluoride (SF₆), an insulator oil, or other suitable materials to provide insulating properties within a volume. In some implementations, a reaction chamber is provided without a partition between the first portion and second portion.

The ICP system 100 can include one or more process gas inlets 121 configured to flow (for example, inject) a processing gas into the chamber 110 from a processing gas source 122. The processing gas supplied by processing gas source 122 can be or include any of a number of different gases suitable for ICP processes, such as tetrafluoromethane (CF₄), sulfur hexafluoride (SF₆), hydrogen chloride (HCl), chlorine (Cl₂), hydrogen bromide (HBr), boron trichloride (BCl₃), fluoroform (CHF₃), oxygen (O₂), water vapor (H₂O), nitrogen (N₂), octafluorocyclobutane (C₄F₈), hydrogen iodide (HI), helium (He), argon (Ar), mixtures thereof, or other suitable ICP process gases.

The process gas inlets 121 can have any suitable configuration to facilitate fluid communication between the gas source 122 (which can be a gas container or a vaporizer for reactants that are not gaseous under standard conditions) and the interior of the reaction chamber 110, and can include any of a number of different nozzles, orifices, conduits, channels, or other features. The inlets 121 can be positioned on or proximate to any of a variety of portions of the reaction chamber 110, such as the sidewalls 111 and/or the partition 140. The inlets 121 can be included in suitable quantities and/or spacing within the reaction chamber 110 to affect the distribution of the processing gas, and thus the plasma distribution, when plasma is formed within the reaction chamber 110. Any of a number of different components can be included in combination with the inlets 121 and the gas source 122 to control the flow of gas into the reaction chamber 110, such as valves, gas panels, flow regulators, sensors, and/or other components.

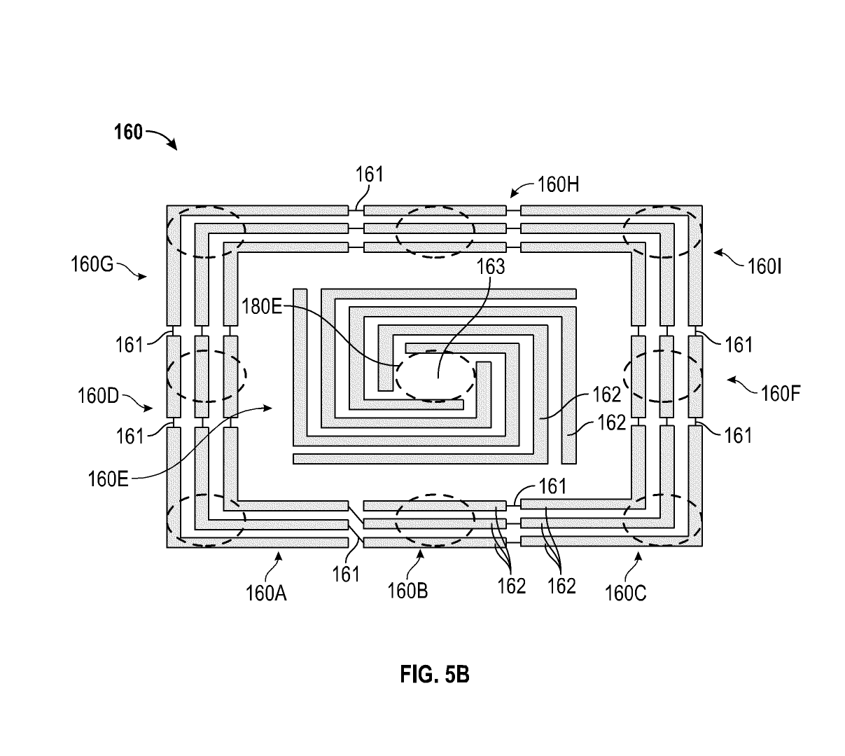

The power sources described herein, such as power source 170, can be any of a number of different types of power sources suitable to power inductive coils, or sections of inductive coils, to induce an inductively-coupled plasma within the reaction space that is defined within the first portion 120 of the reaction chamber 110. For example, the power sources can include a radio frequency (RF) power supply configured to alternate at a frequency of between about 100 kHz and 100 MHz. In an implementation, the RF power supply operates at approximately 13.56 MHz. In some implementations, two or more power sources can be attached to two or more inductive coils or sections of inductive coils, to provide additional control over the distribution of power. The ICP system 100 can include other power sources, such as for electrostatic attraction of the substrate and/or bias for direction plasma processing, as is discussed and illustrated with respect to FIG. 6 below.

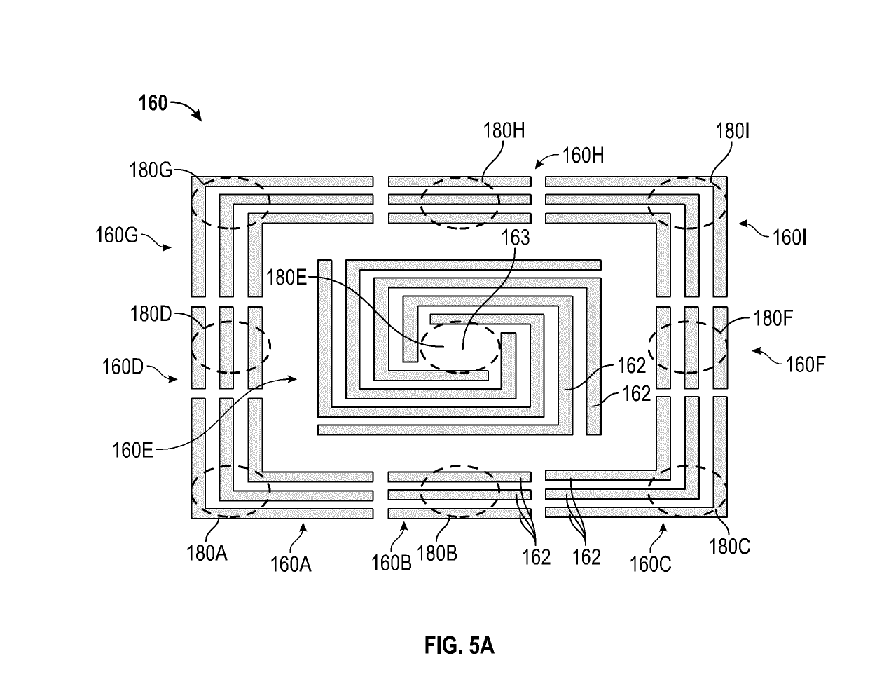

FIG. 5A is an example of a top plan view of a plurality of inductive coil sections 160A-160I with a plurality of adjustment mechanisms 180A-180I, in accordance with one implementation. The adjustment mechanisms 180A-180I are shown with phantom lines in FIG. 5A so that the underlying structure is apparent, and because the adjustment mechanisms are not required for each and every coil section 160A-160I, as described further herein.

The inductive coil sections described herein can be configured in any of a number of different ways suitable to induce an inductively-coupled plasma within the reaction space of the first portion 120 of the reaction chamber 110. Generally, the coil sections each include a wire or suitable structure configured to receive an electric current and connected to other coil sections in a manner defining an overall coiled or spiral shaped current path, which in turn produces energy by electromagnetic induction through time varying magnetic fields, which in turn produce plasma in the gases in the reaction space. Referring, for example, to FIG. 5A, the coil sections can each include coil segments 162, with the segments 162 grouped into different quantities and/or patterns to form the coil sections 160A-160I.

FIG. 5B is an example of a top plan view of a plurality of inductive coil sections 160A-160I showing electrical connections among sections, in accordance with an implementation. The adjustment mechanisms 180A-180I are shown with phantom lines in FIGS. 5A and 5B so that the underlying structure is apparent, and because the adjustment mechanisms are not required for each and every coil section 160A-160I, as described further herein.

In some implementations, the inductive coil sections described herein can form a part of a common inductive coil connected to a single power source, or can form a part of two or more different inductive coils with their own power sources. For example, system 100 can include two or more inductive coil sections that are electrically coupled to each other to form a common inductive coil. FIG. 4 shows an implementation of system 100 with a coil 260A with two or more coil sections 160A and 160B that are coupled to each other with a flexible electrical coupler 161. FIG. 5B shows an implementation of the coil 160 with multiple coil sections 160A, 160B, 160C, 160D, 160F, 160G, 160H and 160I, the segments 162 of which are coupled to each other with flexible electrical couplers 161.

In some implementations, system 100 can include two or more coils, including a first coil with one or more inductive coil sections, and a second coil with one or more inductive coil sections, with the first coil and the second coil not coupled with respect to each other. For example, referring again to FIG. 4, system 100 can include, the first coil 260A with coil sections 160A and 160B, and a second coil 260B with coil section 160C. In FIG. 5B, a first coil can include coil sections 160A, 160B, 160C, 160D, 160F, 160G, 160 H and 160I, while a second coil includes coil section 160E.

In some implementations, two or more inductive coil sections can be configured to induce an inductively-coupled plasma within two or more plasma reaction zones. Providing two or more coil sections can allow individual control and adjustment of the plasma reaction zones corresponding to the coil sections, which in turn can allow adjustment of the resulting process characteristics, such as uniformity, on corresponding zones of a workpiece. For example, referring to FIGS. 3 and 4, inductive coil sections 160A and 160B can be configured to induce an inductively-coupled plasma within a first reaction zone 191A, and a second reaction zone 191B, respectively. FIG. 4 shows a third coil section 160C corresponding with a third reaction zone 191C for illustrative purposes. The shape of the reaction zones corresponding to the coil sections described herein can overlap, be approximately aligned with respect to each other (for example, with an approximately aligned edge or perimeter), or be spaced from each other.

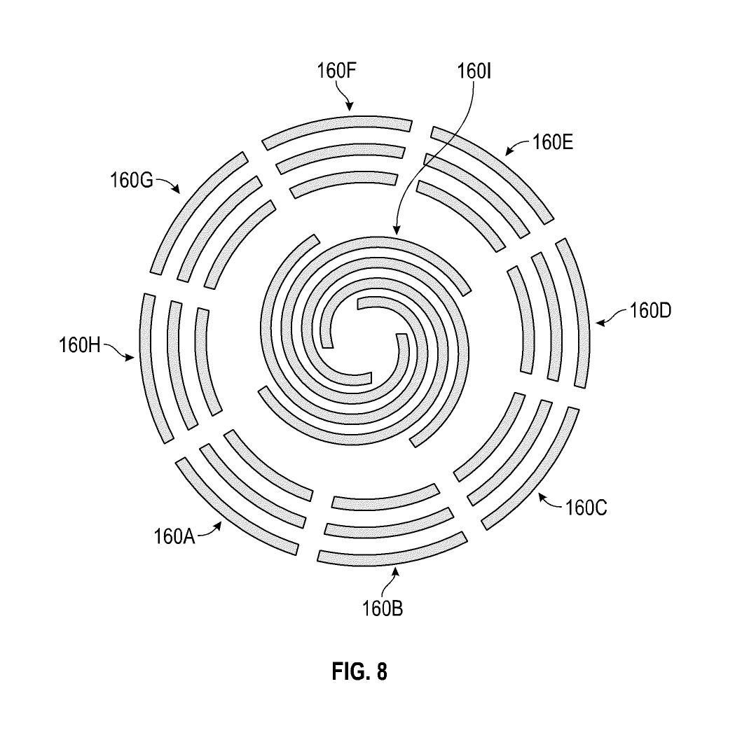

In some implementations, individual control and adjustment of two or more inductive coil sections can be provided through mechanical means. In some implementations, the ICP system can include one or more adjustment mechanisms configured to move one or more inductive coil sections with respect to each other, and/or with respect to other components of the system. The adjustment mechanism(s) can be configured to cause or allow relative motion (e.g., rotational, linear, pivoting motion) between two or more components of an ICP system. The adjustment mechanism(s) can include one or more of, or a combination of, e.g., a hub, bearing, hinge, pin, ball and pinion, axle, rotational joint, clutch, disc, gear, belt, motor, linear slide, actuator (linear, rotational, etc.), screw assembly, track, groove, slot, cam, robot (1, 2, 3, 4 or more axes) etc. It will be understood that an adjustment mechanism can be, but is not necessarily, tied to an electronic, motorized, or otherwise automatic system, and that implementations of adjustment mechanisms described herein can be configured to be moved manually, semi-automatically, and/or automatically (e.g., by a motor, such as a stepper motor). In some implementations, the ICP system can include a motor operatively linked to an adjustment mechanism, with the adjustment mechanism capable of movement in response to the operation of the motor. In some implementations, the system 100 can include a control system (for example, the control system 1000; FIG. 9), with the adjustment mechanism capable of movement in response to a signal (for example, an electronic signal) provided by the control system.

Referring to FIGS. 3 and 4, the adjustment mechanism 180 can be configured to cause or allow movement of two or more inductive coils or coil sections approximately vertically (i.e., toward or away from the workpiece 150), as shown by directional arrows 901, and/or horizontally, as shown by directional arrows 902, and/or in other directions, with respect to each other. In some implementations, the adjustment mechanism(s) 180 can allow movement of one or more inductive coils or coil sections in one or more of these directions relative to other features of the system 100. The adjustment mechanism(s) 180 can allow relative movement of coil sections 160A and 160B with respect to each other. The adjustment mechanism(s) 180 can allow relative movement of coil sections 160A and/or 160B with respect to other features of the system 100, such as the workpiece support 150, the workpiece 500 positioned on the workpiece support 150, and/or the partition 140. Such movability can improve the control of plasma processing characteristics, such as the plasma density and distribution, within the reaction zones of the system 100.

It will be understood that an adjustment mechanism is not necessarily included for each and every inductive coil section. For example, referring to FIG. 3, an adjustment mechanism 180 can be included to provide movement of coil section 160A relative to coil section 160B, without an additional adjustment mechanism being configured to adjust coil section 160B. However, in some implementations, a second adjustment mechanism 180 can be included and configured to adjust coil section 160B (see FIG. 4). In some implementations, an adjustment mechanism can be provided for each inductive coil section (see FIG. 5A).

Some implementations can additionally provide adjustment of plasma formation in the reaction zones through electrical zoning of two or more inductive coil sections or segments relative to each other. Such zoning can be provided by including one or more electrical components that can vary the electrical characteristics (for example, power) flowing into, and/or between two or more inductive coil sections. In some implementations, electrical zoning can be provided through two or more power supplies coupled to two or more corresponding inductive coil sections. For example, referring to FIG. 4, a first power supply 170 can be coupled to coil sections 160A and 160B, and a second power supply 170 can be coupled to coil section 160C. In some implementations, the coupling 161 between a first coil section and second coil section can include one or more, or a combination of, capacitors, resistors, or other electrical component(s) that can vary the distribution of operational power of the two coil sections relative to each other, and thus vary the characteristics of the plasma reaction zones created by each coil section.

Continuing to refer to FIG. 4, one or more flexible couplers 161 can be included to couple two or more coil sections to each other, such as sections 160A and 160B. The couplers described herein can include any of a number of different shapes and sizes suitable to electrically couple two coil sections or segments to each other. The couplers generally are sufficiently flexible to allow relative movement between two coil sections described further herein. FIG. 5B shows a pattern of couplers 161 that joins individual segments 162 in an overall, single line spiral pattern.

FIG. 6 is an example of a cross-sectional side view of an inductively-coupled plasma (ICP) etch system 200. The ICP etch system 200 can include many of the features described herein generally for an ICP system such as ICP system 100 (FIGS. 3 and 4). System 200 can include four adjustment mechanisms 180 corresponding to four inductive coil sections 160A-160D. Couplers 161 can connect coil sections 160A-160D to form a common coil 160. The quantities of the adjustment mechanisms, coil sections and couplers are not specific to the implementation of FIG. 6; other quantities can be employed.

It will be understood that the couplers 161 merely schematically indicate electrical connection among the various independently movable coil sections 160A-160D. Actual connections among various segments of the coil sections can be more complicated than shown, as will be better understood from the various plan views illustrated herein. Additionally, height differences among the various coil sections can be in the range of about 0.5 mm to about 30 mm, more particularly about 5 mm to 15 mm, and is exaggerated in the schematic cross-sections for purposes of illustration.

System 200 can include a pump system 210 configured to evacuate an interior volume of lower portion 120 of the reaction chamber 110. The pump system 210 can include any of a number of different components suitable to provide and/or control such evacuation, such as one or more pumps, valves, regulators, sensors (e.g., pressure sensors, temperature sensors, flow sensors, etc.), and other components, or combinations thereof. In the implementation shown, the pump system 210 includes a dry pump 211 for evacuating process by-products from the reaction chamber 110, a high vacuum turbo molecular pump 212 for evacuating the reaction chamber 110 to a low pressure (typically in the milliTorr range), and a valve 213 for controlling the evacuation from the reaction chamber 110.

The workpiece support 150 can include a support base 151 suitably configured to support the workpiece 500. The support base 151 may be or include, for example, material that is thermally and/or electrically conductive. The support base 151 may be or include aluminum, stainless steel or copper.

In some implementations, a portion of the workpiece support 150, such as the support base 151, can be configured as an electrode powered by a power supply 275 to produce a bias. For example, the support base 151 can be configured as an electrode in implementations for which plasma etch system 200 performs an etch process that includes a mechanical (for example, sputter) etch component. Like the ICP coil power supply 170, the biasing power supply 275 can apply RF power.

An insulator 152 can surround a portion, or substantially the entirety, of base 151 to electrically and/or thermally isolate base 151 from another portion of system, such as a portion of chamber 110. Insulator 152 may be or include any of the insulating and/or chemically resistant materials described herein with respect to the partition 140, such as a ceramic. In some implementations, insulator 152 can be or include aluminum oxide (Al₂O₃), yttrium oxide (Y₂O₃), polyimide resin (for example, Vespel® sold by Dupont), polytetrafluoroethylene (for example, TEFLON® sold by Dupont), polybenzimidazole (PBI), quartz, or similar materials.

In some implementations, one or more channels can be configured to extend within, or in some implementations, through, a portion of workpiece support 150. For example, channels can be configured to flow a fluid (e.g., liquid or gas), within or through a portion of workpiece support 150 from a fluid source. In some implementations, the fluid source can be part of a system, such as a water chiller, configured to heat, cool and provide temperature control through a temperature-control fluid. For example, one or more channels 155 can be provided to flow a fluid (for example, liquid) from a water chiller 223 and through workpiece support 150. Such fluid flow can control the temperature of the workpiece support 150 and/or the workpiece 500 positioned on the workpiece support 150. The temperature control range of the water chiller 223 can be from approximately −60 to 260 degrees Celsius, or in some implementations, from −20 to 100 degrees Celsius. Such temperature control can be provided to heat or cool the workpiece support and/or workpiece 500. For example, it may be desirable to cool the workpiece support 150 in view of the high temperatures generated by a plasma process within the system 200. In some implementations, one or more channels 153, which can be separate from the channels 155, can be configured to allow a fluid (for example, helium gas) to flow from a fluid source 222 through channels 153 to the backside of the workpiece 500 positioned over the workpiece support 150. In turn, the fluid can “float” the workpiece 500 above the workpiece 500, for more uniform thermal contact between the workpiece support 150 and the workpiece 500. Any of a number of different fluids suitable for controlling temperature of the workpiece support 150 and/or floating the workpiece 500 can be used. In some implementations, the fluid may be or include helium or another inert gas.

The workpiece 500 can be held or supported by the workpiece support 150 using any of a number of different structures. The workpiece support 150 can be configured to reduce contact between the workpiece 500 and workpiece support 150 to reduce contamination and/or damage to the workpiece 500. For example, workpiece support 150 may include an edge-grip susceptor, or a recessed (concave) susceptor.

In some implementations, an electrode 154 can be configured within, along or adjacent to a portion of workpiece support 150, such as insulator 152. The electrode 154 can be powered by a DC power supply 270 which in turn creates an electrostatic charge for attracting the workpiece 500 to the workpiece support 150. The electrode 154 and power supply 270 can be used, for example, in combination with the above-mentioned floating workpiece implementation, to attract a workpiece 500 while it is being floated above the workpiece support 150.

The inductive coils, coil sections and coil segments described herein can be configured in a number of different shapes, patterns and configurations, to provide different process results. Referring again to FIG. 5A, a plurality of coil sections 160A-160I can be configured to form a pattern of inductive coil sections having an approximately rectangular shape. A rectangular shape can allow zoned ICP processing control on portions of a workpiece, such as portions proximate to or extending along the corners or edges of a rectangular workpiece. FIG. 5A also shows an implementation in which a plurality of outer coil sections 160A-160D and 160E-160I form a perimeter around one or more inner coil sections, such as inner coil section 160E. Such an implementation can provide tunable plasma intensity over inner vs. outer regions or zones of the workpiece 500; as well as tuning relative plasma intensity at multiple regions or zones along the periphery. FIG. 5A also shows an implementation in which a coil section, such as coil section 160E, is configured with a plurality of segments 162 that each form a lateral spiral or coil extending laterally outwardly from a central portion 163. The “multi line” spiral pattern formed by the plurality of segments 162 of coil section 160E can provide an increased conductance and a lower resistive loss than some other coil configurations. In some implementations, the plurality of segments 162 in coil section 160E can be connected to each other, to form a “single line” spiral pattern such as that described above with respect to sections 160A-160D and 160E-160I in FIG. 5B.

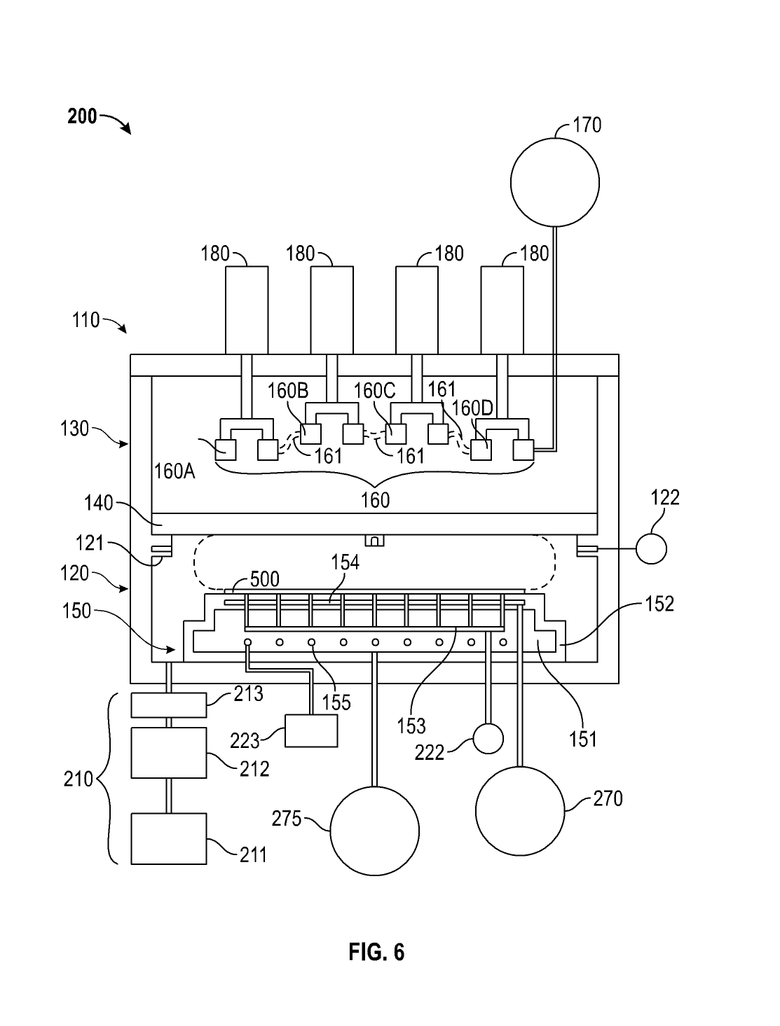

FIG. 7 is an example of a top plan view of a plurality of inductive coil sections 160A-160I with a corresponding plurality of adjustment mechanisms 180A-180I. FIG. 7 can be configured to form a pattern of inductive coil sections having a rectangular shape. A rectangular shape can allow zoned ICP processing control on portions of a workpiece, such as portions proximate to or extending along the corners or edges of a rectangular workpiece. While illustrated as square, one having ordinary skill in this field can understand how the pattern can be extended for non-square rectangular workpieces. Like FIG. 5A, FIG. 7 also shows an implementation in which a plurality of outer coil sections 160A-160D and 160E-160I form a perimeter around one or more inner coil sections, such as inner coil section 160E. FIG. 7 also shows an implementation in which a plurality of coil sections are configured with a plurality of segments 161 that each form a spiral or coil extending laterally outwardly from a central portion 162, although each section could alternatively define a single spiral segment. FIG. 7 also shows an implementation wherein coil sections 160A-160I are positioned in rows and columns to form an array of independently movable inductive coil sections. The number of rows and columns can be varied, and is not limited to a three row by three column array shown in FIG. 7. Such an implementation can be scaled to any desired level of granularity for tuning purposes.

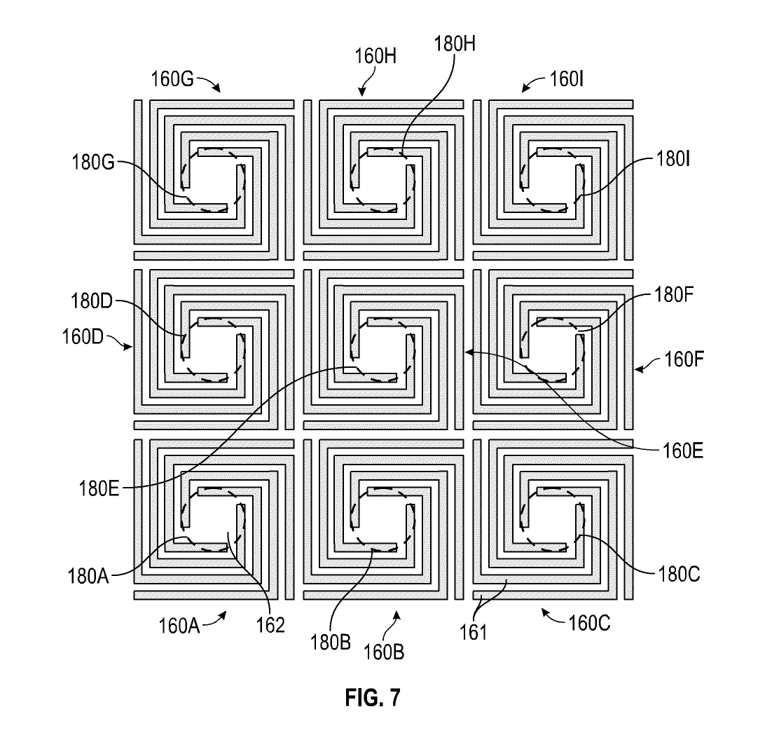

FIG. 8 is an example of a top view of a plurality of inductive coil sections 160A-160I that can be configured to form a pattern of inductive coil sections having an approximately circular shape. A circular shape can allow zoned ICP processing control on portions of a workpiece that is an approximately circular shape, such as a semiconductor substrate used for IC processing.

FIG. 9 is an example of a system block diagram illustrating an inductively-coupled plasma system 100 including a control system or controller 1000 to control various features of, or methods provided by, one or more other components of plasma system 100, such as the plasma reaction chamber 110. The ICP system 100 can be controlled electronically, but can include other types of control sub-systems or components such as pneumatic or hydraulic. The control system 1000 can include any of a number of configurations, and can include any of a variety of controllers, user interfaces, buttons, switches, circuits, and the like. The control system 1000 can control any of the number of components of the reaction chamber 110. For example, the control system 1000 can control the flow of gas into the reaction chamber, or within portions of the reaction chamber. The control system 1000 can control the power to the various power supplies described herein, including the power to the coil sections within the reaction chamber. The control system 1000 can control the relative movement of one or more of the coil sections through electrical control of stepper motors, for example, and the robotics implementing movement of the substrate to and from the reaction chamber 110. In some implementations, the control system 1000 can be in communication with, and/or can be a part of, a control system and/or network within a facility for fabricating electromechanical system devices and/or integrated circuit devices.

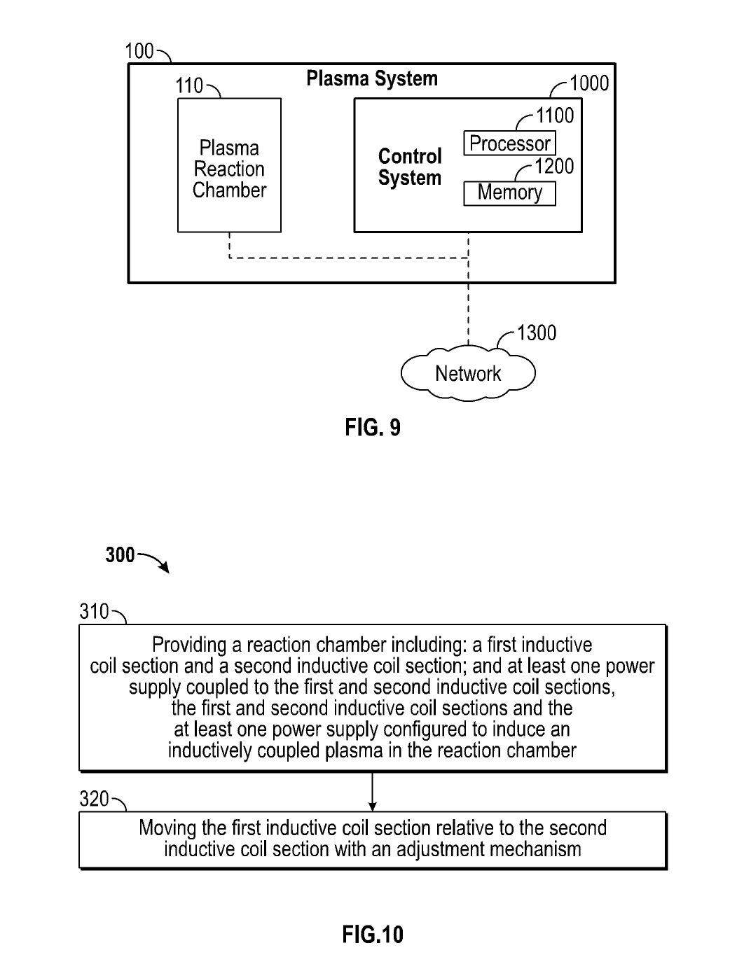

In some implementations, the control system 1000 can be hard-wired to the components or sub-components of ICP system 100, or can be configured to control the components or sub-components wirelessly. The control system 1000 can be in communication with a network 1300. The control system 1000 can be attached to a portion of ICP system 100 (for example, reaction chamber 110) or can be separate from such a portion of ICP system 100. In some implementations, the control system 1000 can be configured to control various aspects of the ICP system 100 remotely (e.g., through a telecommunication system, wirelessly, and/or an additional control system that sends a control signal to control system 1000, etc.), that allow remote interaction with and control one or more ICP systems 100 and their components, for example, from a central station. The control system 1000 can include a processor 1100, which can be a central processing unit (CPU), a microcontroller, or a logic unit. In some implementations, the control system 1000 can include a memory 1200, which can be local to the remainder of control system 1000, or can be located remote from the remainder of control system 1000 (for example, through cloud computing methods). The memory 1200 can include programming for conducting processing on workpieces in sequence, including the method of FIG. 10, described below.

FIG. 10 is an example of a flow diagram illustrating a method 300 of plasma-processing a substrate. The method 300 can include providing a reaction chamber at block 310. The reaction chamber can include a first inductive coil section and a second inductive coil section, and at least one power source coupled to the first and second inductive coil sections. The first and second inductive coil sections and the at least one power source can be configured to induce an inductively coupled plasma in the reaction chamber. At block 320, the method includes moving the first inductive coil section relative to the second inductive coil section with an adjustment mechanism.

In some implementations, moving includes automatically moving the first inductive coil section. In some implementations, moving includes moving the first inductive coil section relative to the second inductive coil section with a stepper motor. In some implementations, moving includes moving the first inductive coil section relative to an isolating partition positioned between a coil chamber within which the first and second inductive coil sections are located and a reaction space of the reaction chamber. In some implementations, providing the reaction chamber further includes providing additional inductive coil sections within the coil chamber, and moving includes moving the first, second, and additional inductive coil sections with separate adjustment mechanisms. In some implementations, the method further includes adjusting relative power distribution between the first inductive coil section and the second inductive coil section. In some implementations, the at least one power source includes a first power source and a second power source, and adjusting relative power distribution includes providing a first power to the first inductive coil section with the first power source and providing a second power to the second inductive coil section with the second power source. In some implementations, the method further includes injecting a processing gas into the reaction space of the reaction chamber, and inducing an inductively coupled plasma in the reaction space from the processing gas. In some implementations, the method further includes etching a workpiece positioned on a workpiece support within the reaction space with the inductively coupled plasma. In some implementations, the method further includes depositing a film on a workpiece positioned on a workpiece support within the reaction space with the inductively coupled plasma. In some implementations, the method further includes plasma processing a workpiece on the workpiece support simultaneously with or at a different time than the moving the first inductive coil section relative to the second inductive coil section.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various methods described in connection with the implementations disclosed herein may be implemented manually or through automation controlled by electronic hardware, computer software, or combinations of both. Whether such functionality is implemented in hardware or software depends upon the particular application and design constraints imposed on the overall system.

For automated control, the hardware and data processing apparatus used to implement the functionability described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, for example, inductive coils relative to the workpiece in some implementations.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An inductively coupled plasma system, comprising:
a reaction chamber including a reaction space and a coil chamber;
a workpiece support within the reaction space;
a first inductive coil section and a second inductive coil section within the coil chamber, the first and second inductive coil sections being independently movable;
at least one power source coupled to the first and second inductive coil sections, the first and second inductive coil sections and the at least one power source configured to induce an inductively coupled plasma in the reaction space; and
an adjustment mechanism configured to move the first inductive coil section relative to the second inductive coil section.

2. The inductively coupled plasma system of claim 1, wherein the at least one power source is a single power source communicating with both the first and second inductive sections.

3. The inductively coupled plasma system of claim 1, wherein the adjustment mechanism includes one or more stepper motors.

4. The inductively coupled plasma system of claim 3, wherein the one or more stepper motors includes a stepper motor for each of the first and second inductive coil sections.

5. The inductively coupled plasma system of claim 1, wherein the adjustment mechanism is configured to be moved automatically.

6. The inductively coupled plasma system of claim 1, further comprising an isolating partition between the coil chamber and the reaction space, wherein the adjustment mechanism is configured to move the first inductive coil section relative to the isolating partition.

7. The inductively coupled plasma system of claim 1, further including additional inductive coil sections within the coil chamber, the system further including separate adjustment mechanisms for each of the first, second and additional inductive coil sections.

8. The inductively coupled plasma system of claim 1, further including a flexible connector configured to electrically couple the first and second inductive coil sections.

9. The inductive coupled plasma system of claim 8, further including a capacitor configured to adjust relative power distribution between the first and second inductive coil sections.

10. The inductive coupled plasma system of claim 1, wherein the at least one power source includes a first power source coupled to the first inductive coil section and a second power source coupled to the second inductive coil section.

11. The inductively coupled plasma system of claim 1, wherein the first and second inductive coil sections form at least part of a pattern of inductive coil sections within the coil chamber collectively having an approximately rectangular shape.

12. The inductively coupled plasma system of claim 11, wherein the pattern of inductive coil sections includes a plurality of outer coil sections that form a perimeter around an inner coil section.

13. The inductively coupled plasma system of claim 11, wherein the pattern of inductive coil sections include an array of spaced inductive coil sections.

14. The inductively coupled plasma system of claim 1, further including a gas source communicating with the reaction space, the gas source being suitable for plasma dry etching.

15. The inductively coupled plasma system of claim 14, wherein the at least one power source includes a radio frequency power source, further including a biasing power source connected to the workpiece support.

16. The inductively coupled plasma system of claim 15, further including a DC power source for electrostatically attracting a substrate to the workpiece support.

17. A method of plasma-processing a workpiece, comprising:
providing a reaction chamber including:
a first inductive coil section and a second inductive coil section; and
at least one power source coupled to the first and second inductive coil sections, the first and second inductive coil sections and the at least one power source configured to induce an inductively coupled plasma in the reaction chamber; and
moving the first inductive coil section relative to the second inductive coil section with an adjustment mechanism.

18. The method of claim 17, wherein moving includes automatically moving the first inductive coil section.

19. The method of claim 18, wherein moving includes moving the first inductive coil section relative to the second inductive coil section with a stepper motor.

20. The method of claim 17, wherein moving includes moving the first inductive coil section relative to an isolating partition positioned between a coil chamber within which the first and second inductive coil sections are located and a reaction space of the reaction chamber.

21. The method of claim 17, wherein providing further includes providing additional inductive coil sections within the coil chamber, wherein moving includes moving the first, second, and additional inductive coil sections with separate adjustment mechanisms.

22. The method of claim 17, further including adjusting relative power distribution between the first inductive coil section and the second inductive coil section.

23. The method of claim 22, wherein the at least one power source includes a first power source and a second power source, and adjusting relative power distribution includes providing a first power to the first inductive coil section with the first power source and providing a second power to the second inductive coil section with the second power source.

24. The method of claim 17, further including injecting a processing gas into a reaction space of the reaction chamber, and inducing an inductively coupled plasma in the reaction space from the processing gas.

25. The method of claim 24, further including etching a workpiece positioned on a workpiece support within the reaction space with the inductively coupled plasma.

26. The method of claim 24, further including depositing a film on a workpiece positioned on a workpiece support within the reaction space with the inductively coupled plasma.

27. An inductively coupled plasma system, comprising:
a reaction space;
a workpiece support within the reaction space;
a means for inducing an inductively coupled plasma in the reaction space; and
adjustment means for moving a first section of the means for inducing relative to a second section of the means for inducing.

28. The inductively coupled plasma system of claim 27, wherein the adjustment means includes a stepper motor.

29. The inductively coupled plasma system of claim 27, wherein the adjustment means includes a separate stepper motor for each of the first and second sections of the means for inducing.

30. The inductively coupled plasma system of claim 27, wherein the means for inducing includes means for adjusting relative power distribution between the first and second sections.

31. The inductive coupled plasma system of claim 30, wherein the means for adjusting relative power distribution includes a first power source in electrical communication with the first section, and a second power source in electrical communication with the second section.
